(19) United States
(12) Patent Application Publication
(10) Pub. No.: US 2008/0029772 A1
(43) Pub. Date: Feb. 7, 2008

(54) LIGHTING STRUCTURE WITH LIGHT EMITTING DIODES AND METHOD OF FORMING SAME

(76) Inventor: Cheng-Ting Chiang, Sinihuang City (TW)

Correspondence Address: SNELL & WILMER L.L.P. (Main), 400 EAST VAN BUREN, ONE ARIZONA CENTER, PHOENIX, AZ, 85004-2202, US

(21) Appl. No.: 11/567,875

(22) Filed: Dec. 7, 2006

(30) Foreign Application Priority Data
Aug. 4, 2006 (TW) 95128679

(51) Int. Cl. H01L 33/00

(52) U.S. Cl. 257/88

(57) ABSTRACT

A light module and a method of forming the module are disclosed. The light module includes a plurality of light units and a module substrate having a patterned circuit layer on a first surface of the module substrate and a plurality of openings for accommodating the light units. Each light unit includes a metal substrate, a plurality of light emitting diode (LED) chips mounted on a first surface of the metal substrate, a plurality of conductive layers for respectively connecting a positive terminal and a negative terminal of each LED to the patterned circuit layer, an insulating layer on the metal substrate for separating the plurality of conductive layers from the metal substrate; and a bearing layer formed above the metal substrate, and configured to support the module substrate and the optical lens.

### CROSS REFERENCE TO RELATED APPLICATIONS

This application claims the right of priority based on Taiwan Patent Application No. 095128679 entitled “A Lighting Structure With Light Emitting Diodes and the Method Thereof,” filed on Aug. 4, 2006, which is incorporated herein by reference and assigned to the assignee herein.

### FIELD OF INVENTION

The invention is related to a light module, and more particularly to packaging and assembling of the lighting module with light emitting diodes (LEDs).

### BACKGROUND OF THE INVENTION

A conventional method of packaging an LED lighting module is first to package the LED chip into an LED element 100, as shown in FIG. 1. Then, multiple LED elements 100 are assembled as a light bar 200 on a circuit board 292, e.g. a printed circuit board (PCB), as shown in FIG. 2. Multiple light bars 200 may be arranged in rows or columns to form a back light module 300, as shown in FIG. 3.

However, various light bars with different lengths must be prepared for products with different sizes. Thus, the approach of packaging then assembling light bars of different lengths is expensive, and it typically lacks optical lenses to efficiently control the light energy. Consequently, as the number of LEDs utilized increases, conventional lighting modules become less competitive.

Therefore, an improved method and a structure to directly mount LED chips onto a metal substrate different from the conventional LED light bars, so that a light module with high heat sink performance is achieved, which is suitable for back light or lamp applications, are desired.

### SUMMARY OF THE INVENTION

One aspect of the present invention is to provide a light module, which includes a plurality of light units and a module substrate having a patterned circuit layer on a first surface of the module substrate. Each light unit includes a metal substrate, a plurality of light emitting diode (LED) chips mounted on a first surface of the metal substrate, a plurality of conductive layers for respectively connecting a positive terminal and a negative terminal of each LED to the patterned circuit layer, an insulating layer on the metal substrate for separating the plurality of conductive layers from the metal substrate, and a bearing layer, above the metal substrate, for supporting the module substrate and the optical lens. The module substrate has a plurality of openings for accommodating the optical lens.

Another aspect of the present invention is to provide a method for forming a light module. The method includes (a) forming a plurality of light units, wherein the formation of each light unit includes: (i) providing a metal substrate; (ii) forming an insulating layer on the metal substrate exposing a portion of the metal substrate; (iii) forming a plurality of conductive layers on the insulating layer; (iv) forming a bearing layer on the conductive layers; (v) mounting at least one LED chip on the exposed metal substrate; and (vi) providing an optical lens on the bearing layer; and (b) providing a module substrate having a plurality of openings for accommodating the light units, wherein the conductive layers respectively electrically connect a positive terminal and a negative terminal to a patterned circuit layer of the module substrate.

In another embodiment, the method further includes a step of forming a light-reflecting layer on the module substrate, the metal substrate, or both. In a further embodiment, the method further includes a step of applying fluorescent material so that the color of light emitted from the LED chip is changed. In accordance with yet another embodiment, the method further includes a step of applying a light-absorbable material to the optical lens so as to control the light pattern.

### BRIEF DESCRIPTION OF THE DRAWINGS

FIG. 1 shows a cross-sectional view of a prior art LED.

FIG. 2 shows a cross-sectional view of a prior art light bar, including a plurality of the LEDs of FIG. 1.

FIG. 3 shows a top view of a prior art light module, including multiple light bars of FIG. 2.

FIG. 4 illustrates a cross-sectional view of a light module in accordance with one embodiment of the present invention.

FIG. 5 illustrates a top view of a light unit in accordance with one embodiment of the present invention.

FIG. 6 illustrates a cross-sectional view of a light unit in accordance with one embodiment of the present invention.

FIG. 7A illustrates a cross-sectional view of a light module in accordance with another embodiment of the present invention.

FIG. 7B illustrates a cross-sectional view of a light unit in accordance with another embodiment of the present invention.

FIG. 8 illustrates an arrangement of light units in accordance with one embodiment of the present invention.

FIG. 9 illustrates an arrangement of light units in accordance with another embodiment of the present invention.

FIG. 10A illustrates formation of an optical lens in accordance with one embodiment of the present invention.

FIG. 10B illustrates formation of an optical lens in accordance with another embodiment of the present invention.

FIG. 11 illustrates formation of an optical lens in accordance with a further embodiment of the present invention.

FIG. 12 illustrates formation of an optical lens in accordance with another embodiment of the present invention.

FIG. 13 illustrates an arrangement of an optical lens in accordance with one embodiment of the present invention.

FIG. 14 illustrates an arrangement of an optical lens in accordance with another embodiment of the present invention.

FIG. 15 illustrates an arrangement of an optical lens in accordance with a further embodiment of the present invention.

FIG. 16 illustrates an arrangement of an optical lens in accordance with another embodiment of the present invention.

FIG. 17 illustrates the appearance of an exemplary lens in accordance with one embodiment of present invention.

### DETAILED DESCRIPTION

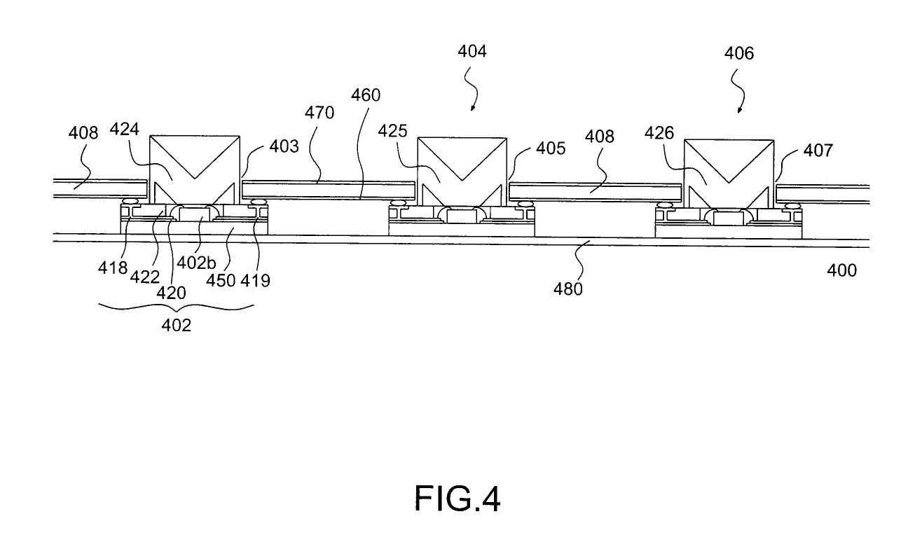

A light module and a method for using the module are disclosed. In the following, the present invention can be further understood by referring to, but is not limited to, the exemplary descriptions accompanied with the drawings in FIG. 4 to FIG. 17.

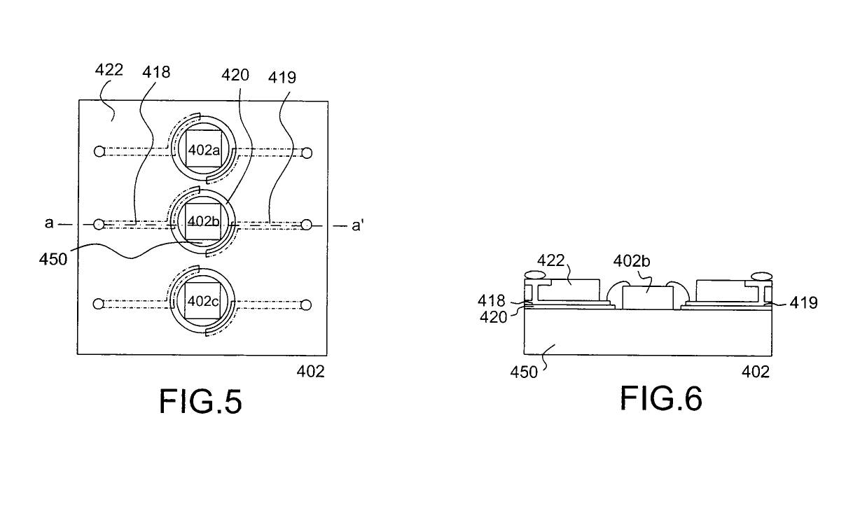

Referring to FIG. 4, in one embodiment, a light module 400 is provided. The light module 400 includes three light units 402, 404, and 406 and a module substrate 408. The module substrate 408 includes multiple openings 403, 405, and 407, which are configured to accommodate the light units 402, 404, and 406, respectively. An exemplary structure of the light units 402, 404 and 406 is shown in FIG. 5 and FIG. 6. Taking the light unit 402 as an example, FIG. 5 is a top view of the light unit 402. The light unit 402 includes a plurality of LED chips, for example, three LED chips 402a, 402b, and 402c. The LED chips 402a, 402b, and 402c are mounted onto a metal substrate 450 using chip-on-board or flip chip on board technology. The metal substrate 450 can be an aluminum substrate, a copper substrate, or any substrate with suitable heat dissipation. Moreover, a positive terminal and a negative terminal of each LED chip, 402a, 402b, or 402c, are respectively connected to its corresponding conductive layer, such as 418 and 419b, via bonding wires.

An insulating layer 420 is located between the metal substrate 450 and the conductive layers 418 and 419 to electrically isolate the metal substrate 450 from the conductive layers 418 and 419, as shown in FIG. 6. A bearing layer 422 is located on the conductive layers 418 and 419 and is configured to support the module substrate 408 and/or an optical lens. It is noted that the module substrate and the optical lens are not shown in FIG. 5 for simplicity and unambiguous purpose. FIG. 6 is a cross-sectional view along the a-a′ line in FIG. 5. Similarly, the module substrate and the optical lens are not shown in FIG. 6 for simplicity and unambiguous purpose.

Referring back to FIG. 4, light units 404 and 406 may have the same structure as the light unit 402. The light unit 402 may include at least one optical lens 424, which can be accommodated in the opening 403 of the module substrate 408. Similarly, the light unit 404 or 406 may also include at least one optical lens 425, 426, accommodated in the openings 405 and 407, respectively. Now taking the light unit 402 for example to further explain the present invention, the light unit 402 includes a plurality of LED chips (e.g. 402a, 402b, and 402c), the insulating layer 420, the metal substrate 450, and the bearing layer 422. In this embodiment, the positive terminal of the LED chip 402b is electrically coupled to a patterned circuit layer 460 through the conductive layer 418, while the negative terminal is electrically coupled to the patterned circuit layer 460 through the conductive layer 419. The patterned circuit layer 460 is on a lower surface of the module substrate 408. In one embodiment, the conductive layers 418 and 419 pass through the bearing layer 422 to connect to the patterned circuit layer 460 by use of pin connection, connector connection, solder connection, or ball grid array (BGA) connection technology. In the embodiment, an upper surface of the module substrate 408 may further include a light-reflecting layer 470, such as a metal film or an optical coating, for mixing or centralizing light. Moreover, the light module 400 may further include a heat conductive layer 480 for efficiently dissipating the heat generated by the light units 402, 404, and 406. The connection between the module substrate 408 and the light units 404 and 406 can be the same as that described above for the light unit 402.

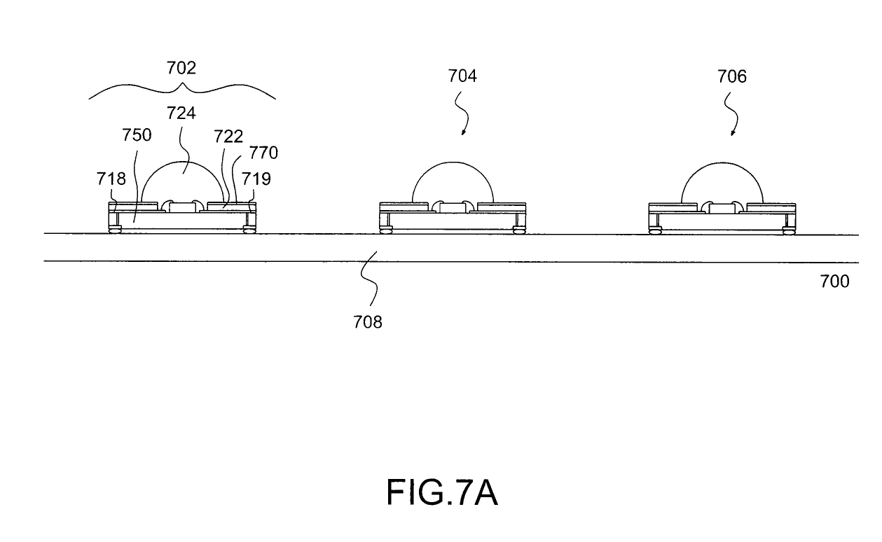

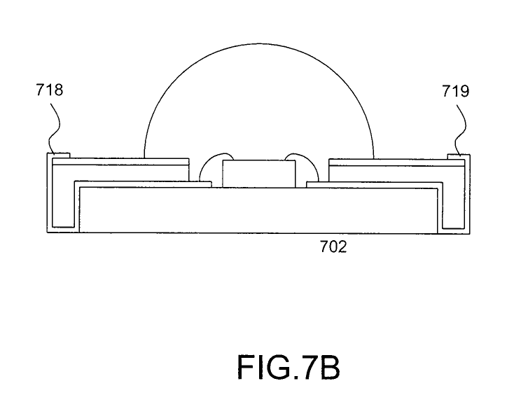

Besides the light module shown in FIG. 4, an alternative light module 700 is shown in FIG. 7A. The light module 700 includes three light units 702, 704, and 706 and a module substrate 708. Similarly, taking the light unit 702 as an example, the light unit 702 includes an optical lens 724, a bearing layer 722, conductive layers 718 and 719, and a metal substrate 750. The conductive layers 718 and 719 pass through the bearing layer 722 to connect to the module substrate 708, i.e. connect to a patterned circuit layer (not shown) on the module substrate 708 using pin connection, connector connection, solder connection, or ball grid array (BGA) connection technology as described above. It is noted that the patterned circuit layer and an insulating layer are not depicted in FIG. 7A. However, it is noted that the patterned circuit layer can be located on an upper surface of the module substrate 708, and the insulating layer is located at a suitable location for electrically isolating the conductive layers 718 and 719 from the metal substrate 750. Furthermore, a light-reflecting layer 770, such as a metal film or an optical coating, may be optionally provided on the bearing layer 722 for mixing or centralizing light. Furthermore, the light-reflecting layer 770 may be formed on suitable locations of the module substrate 708 to enhance optical applications.

The conductive layers 418 and 419 pass through the bearing layer 422 to connect to the patterned circuit layer 460 as shown in FIG. 4, while the conductive layers 718 and 719 pass through the metal substrate 750 to connect to the patterned circuit layer as shown in FIG. 7A. As shown in FIG. 7B, the conductive layers 718 and 719 may have different design to detour around the side of the light unit 702, which can be implemented in the light module as shown in FIG. 4.

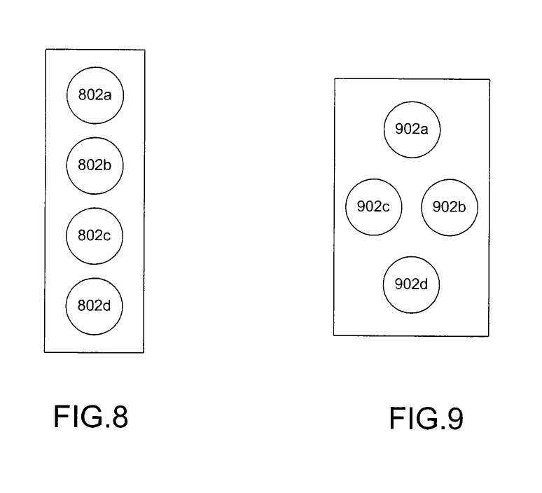

The LED chips on the light unit 702 shown in FIG. 7A can be packaged and arranged in any geometry, such as a straight line similar to the light unit 402 of FIG. 5 or any other suitable arrangements. In one embodiment, four LED chips 802a, 802b, 802c, and 802d may be arranged and packaged as a light unit shown in FIG. 8. Alternatively, four LED chips 902a, 902b, 902c, and 902d may be arranged as shown in FIG. 9. The LED chips shown in FIG. 8 and FIG. 9 can be LEDs with different wavelengths ranging from 420 nm to 680 nm. For example, LEDs 802a, 802d, 902a, and 902c can be green (G) LEDs, while LEDs 802b and 902b are red (R) LEDs, and LEDs 802c and 902c are blue (B) LEDs. By mixing the red, green, blue (RGB) lights generated from the LEDs, a white light can be obtained. Besides RGB, it is well known for those skilled in the art that yellow, magenta, cyan (YMC) lights may be implemented in the present invention to generate a white light. It is noted that though the arrangement in FIG. 8 and FIG. 9 is GRBG, other arrangements may be implemented in the present invention. In other embodiments, the number of LED chips in a light unit may be varied to meet different design needs, such as two, three, five, seven, or the multiples thereof.

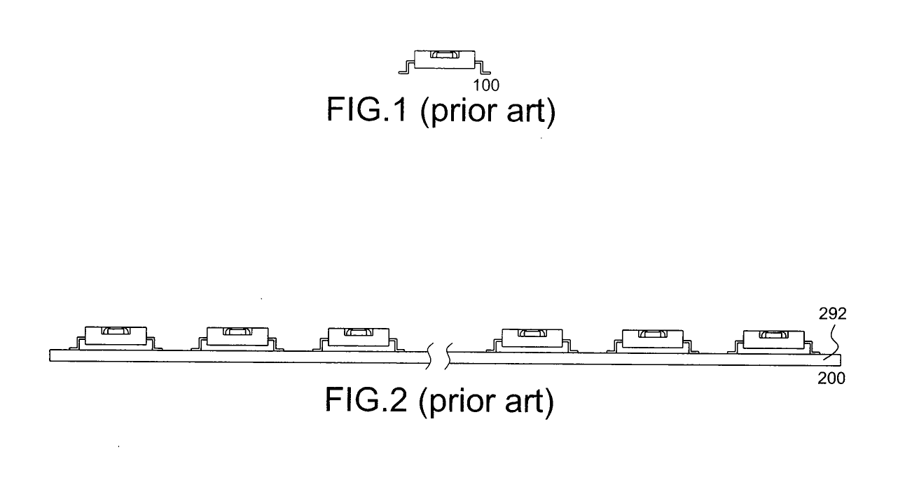

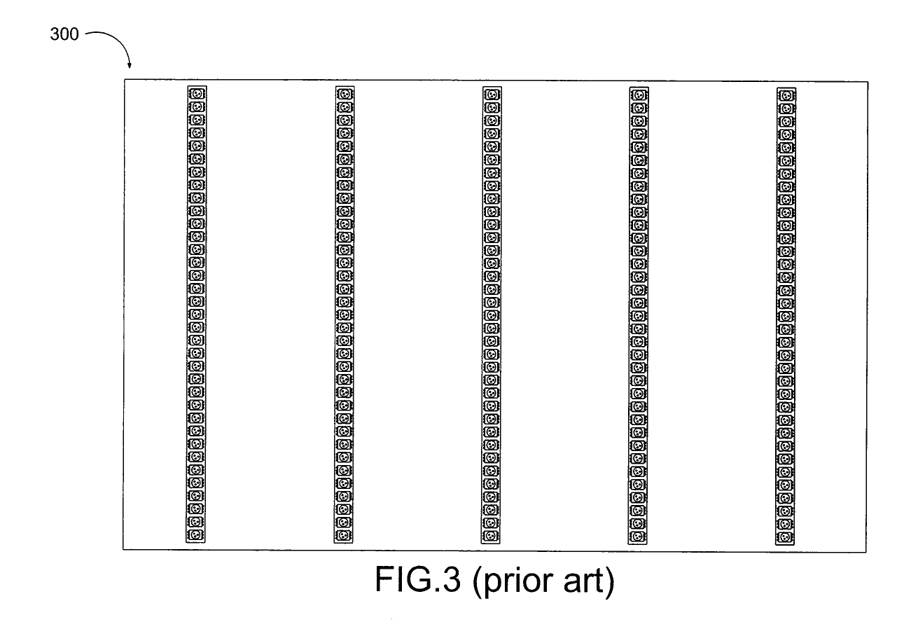

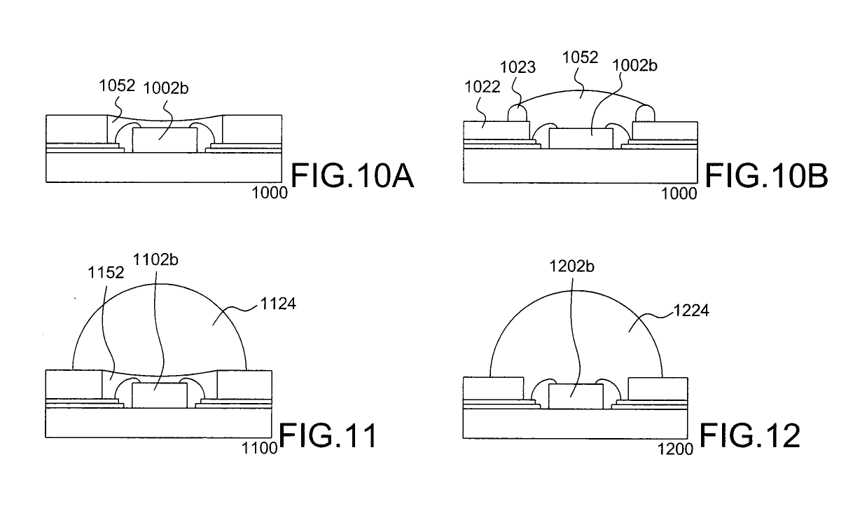

After die mounting and wire bonding, in one embodiment as shown in FIG. 10A, a light unit 1000 is molded by directly injecting polymer adhesive material 1052. Optionally, an optical lens may be positioned on the light unit 1000. As shown in FIG. 10B, in one embodiment, prior to injecting the polymer 1052, a curvature, like a dam shape, may be supported by a protrusion 1023 on a bearing layer 1022 around an LED chip 1002b so as to facilitate the injection of polymer 1052. In another embodiment, polymer 1152 is injected onto a light unit 1100 first, and then an optical lens 1124 is disposed on the light unit 1100, as shown in FIG. 1. In a further embodiment, an optical lens 1224 is directly disposed on the light unit 1200, as shown in FIG. 12. It is noted that the light units in FIG. 10A to FIG. 12 may have similar features, such as a conductive layer, a bearing layer, a metal substrate, an insulating layer, etc., to those in FIG. 4 or FIG. 6.

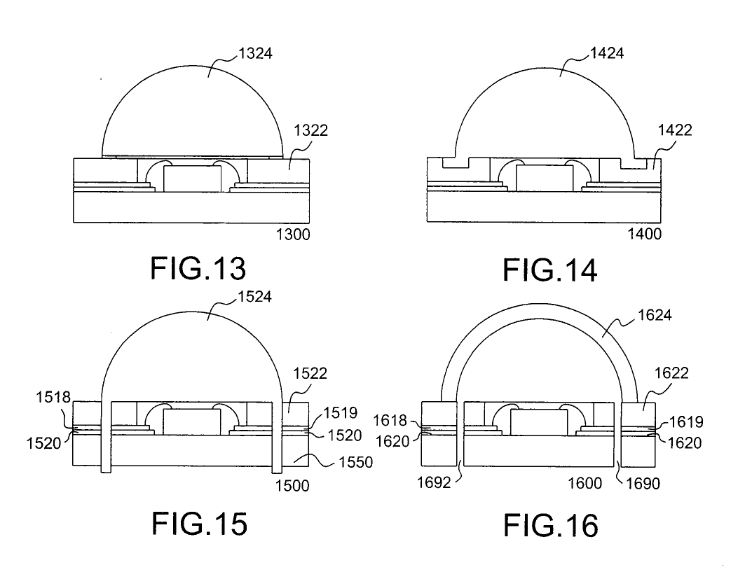

Exemplary arrangements of the optical lens 1124 or 1224 are illustrated in FIG. 13 to FIG. 16. A light unit 1300, 1400, 1500 or 1600 includes a bearing layer 1322, 1422, 1522 or 1622 for supporting an optical lens 1324, 1424, 1524 or 1624, respectively. It is noted that the reference numeral 1520 and 1620 represent an insulating layer, while the reference numeral 1518, 1519, 1618 and 1619 represent a conductive layer, and the numeral 1550 and 1650 represent a metal substrate in FIGS. 15 and 16 respectively. As shown in FIG. 13, the optical lens 1324 is directly attached to the bearing layer 1322 in accordance with one embodiment of present invention. FIG. 14 illustrates that a portion of the optical lens 1424 is embedded into the bearing layer 1422. FIG. 15 illustrates that a portion of the optical lens 1524 is inserted into the bearing layer 1522 passing through the bearing layer 1522, the insulating layer 1520, and the metal substrate 1550. FIG. 16 illustrates that the optical lens 1624 is a hollow optical lens position on the bearing layer 1622. Polymer can be injected through an inlet 1690 filling the space defined by the optical lens 1624 and driving the air inside the space out via the outlet 1692. Therefore, a light unit 1600 having a curve optical lens 1624 with polymer filling is obtained.

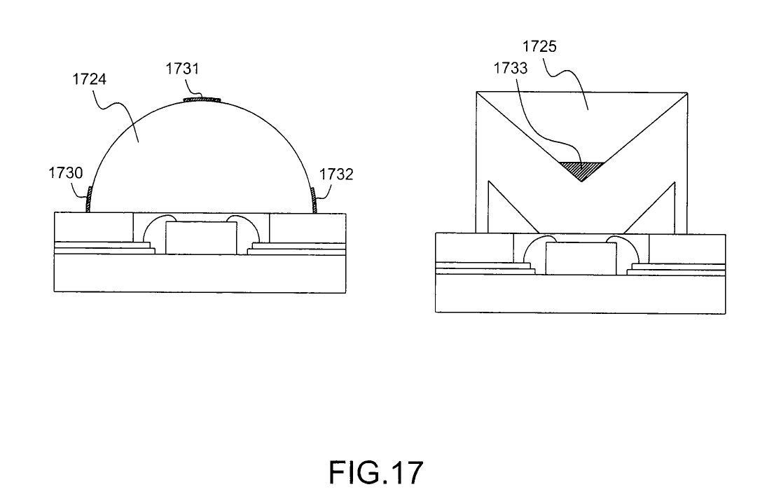

Furthermore, referring to FIG. 17, the optical lenses described above may have different shapes, such as optical lenses 1724 and 1725. Moreover, a light-absorbable material may be attached, applied, or coated to the optical lens 1724 and 1725 at suitable places 1730, 1731, 1732, and 1733 to shade light so as to effectively control the light pattern and stray light.

Furthermore, in one embodiment, fluorescent material can be applied to the light unit after die mounting and prior to the disposition of the optical lens. In one embodiment, blue LEDs with wavelength ranging from 420 nm to 470 nm may be incorporated with the fluorescent material, so that the blue light emitted from blue LEDs will be converted to a white light.

Another aspect of the present invention is to provide a method for forming a light module. The method includes the following steps: (a) forming a plurality of light units, wherein the formation of each light unit includes the following steps: (i) providing a metal substrate, such as an aluminum substrate, a copper substrate, or other metal substrate with high conductivity coefficient; (ii) forming an insulating layer on the metal substrate, wherein the insulating layer exposes a portion of the metal substrate; (iii) forming a plurality of conductive layer on the insulating layer; (iv) forming a bearing layer on the conductive layers; (v) mounting at least one LED chip on the exposed metal substrate using chip-on-board or flip chip on board technology; and (vi) providing an optical lens on the bearing layer; and (b) providing a module substrate having a plurality of openings for accommodating the light units. The conductive layers respectively connect a positive terminal and a negative terminal of the LED chip to a patterned circuit layer of the module substrate, and the bearing layer supports the module substrate. The LED chips include LEDs with different wavelengths, such as RGB LEDs, YMC LEDs, or the combination thereof. Moreover, the method further includes a step of providing a heat conductive layer on the metal substrate of each LED for efficiently dissipating heat.

In accordance with another aspect of the present invention, the method includes the following steps: (a) forming a plurality of light units, wherein the formation of each light unit includes the following steps: (i) providing a metal substrate, such as an aluminum substrate, a copper substrate, or other metal substrate with high conductivity coefficient; (ii) forming an insulating layer on the metal substrate exposing a portion of the metal substrate; (iii) forming a plurality of conductive layers on the insulating layer; (iv) forming a bearing layer on the conductive layers; (v) mounting at least one LED chip onto on the exposed metal substrate using chip-on-board or flip chip on board technology; (vi) applying fluorescent material to at least one light unit; and (vii) providing a plurality of optical lenses on the bearing layer; and (b) providing a module substrate having a plurality of openings for accommodating the light units. The conductive layers respectively connect a positive terminal and a negative terminal of the LED chip to a patterned circuit layer of the module substrate. Moreover, the method further includes a step of providing a reflective layer on the module substrate.

The present invention has been described above with reference to preferred embodiments. However, those skilled in the art will understand that the scope of the present invention need not be limited to the disclosed preferred embodiments. On the contrary, it is intended to cover various modifications and equivalent arrangements within the scope defined in the following appended claims. The scope of the claims should be accorded the broadest interpretation so as to encompass all such modifications and equivalent arrangements.

What is claimed is:

1. A light module, comprising:
a plurality of light units, each light unit having at least one optical lens; and
a module substrate having a patterned circuit layer on a first surface of the module substrate and a plurality of openings for accommodating the at least one optical lens;
wherein each light unit comprises:
a metal substrate;
a plurality of light emitting diode (LED) chips mounted on a first surface of the metal substrate;
a plurality of conductive layers for respectively connecting a positive terminal and a negative terminal of each LED to the patterned circuit layer;
an insulating layer on the metal substrate for separating the plurality of conductive layers from the metal substrate; and
a bearing layer, above the metal substrate, for supporting the module substrate and the optical lens.

2. The light module of claim 1, wherein the metal substrate is an aluminum substrate or a copper substrate, and wherein the LED chips is mounted onto the metal substrate using chip on board or flip chip on board technology.

3. The light module of claim 1, wherein at least one light unit includes a blue LED chip incorporated with fluorescent material.

4. The light module of claim 1, wherein the LED chips comprise red, green, and blue (RGB) LEDs, or yellow, magenta, and cyan (YMC) LEDs.

5. The light module of claim 4, further including a light-reflecting layer on a second surface of the module substrate to mix lights emitted from the LEDs with different wavelengths.

6. The light module of claim 1, further comprising:
a heat conductive layer attached to the metal substrate of each LED.

7. The light module of claim 1, wherein a light-absorbable material is attached, applied or coated to a portion of the optical lens so as to control a light pattern.

8. The light module of claim 1, wherein the conductive layer of the light unit passes through the bearing layer to connect to the patterned circuit layer.

9. The light module of claim 1, wherein the light module is implemented in a back light module or a lamp application.

10. The light module of claim 1, wherein the optical lens is a hollow optical lens and the light unit further comprises an inlet and an outlet for allowing a polymer to fill a space defined by the optical lens.

11. A method for forming a light module, comprising:
(a) forming a plurality of light units, wherein the formation of each light unit comprises:
(i) providing a metal substrate;
(ii) forming an insulating layer on the metal substrate exposing a portion of the metal substrate;
(iii) forming a plurality of conductive layers on the insulating layer;
(iv) forming a bearing layer on the conductive layers;
(v) mounting at least one LED chip on the exposed metal substrate; and
(vi) providing an optical lens on the bearing layer; and
(b) providing a module substrate having a plurality of openings for accommodating the light units,
wherein the conductive layers respectively electrically connect a positive terminal and a negative terminal to a patterned circuit layer of the module substrate.

12. The method of claim 11, wherein the at least one LED chip is mounted on the metal substrate by use of chip-on-board or flip chip on board technology.

13. The method of claim 11, wherein the optical lens is a hollow optical lens, and the method further comprising filling a space defined by the optical lens with polymer in the light unit.

14. The method of claim 11, further comprising a step of applying a light-absorbable material to the optical lens.

15. The method of claim 11, further comprising a step of applying fluorescent material so that the color of light emitted from the LED chip is changed.

16. The method of claim 11, further comprising a step of forming a light-reflecting layer on the module substrate.

17. The method of claim 11, further comprising a step of forming a light-reflecting layer on the metal substrate.

18. The method of claim 11, further comprising a step of providing a heat dissipation layer to the metal substrate.
